(19) United States
(12) Patent Application Publication
(10) Pub. No.: US 2004/0256719 A1
(43) Pub. Date: Dec. 23, 2004

(54) MEMS micro-cap wafer level chip scale package

(75) Inventor: Kuo Lung Lei, San Jose, CA (US)

Correspondence Address: TUNG & ASSOCIATES, Suite 120, 838 W. Long Lake Road, Bloomfield Hills, MI, 48302, US

(73) Assignee: Aptos Corporation

(21) Appl. No.: 10/600,799

(22) Filed: Jun. 18, 2003

(51) Int. Cl. H01L 23/10

(52) U.S. Cl. 257/706

(57) ABSTRACT

A wafer level, chip scale package suitable for a MEMS type device employs a solder bead between a protective cap and the chip substrate to hermetically seal active areas of the chip. Solder is electroplated onto a metallized layer on the cap through a photoresist mask that is subsequently removed to leave a solder bead patterned to completely surround the active chip areas. The cap is mounted on the chip substrate using a spacer to hold the cap and the substrate in spaced relationship while the cap is welded to the chip substrate using the solder bead. The spacer is subsequently removed, preferably during dicing of a wafer on which the chips are formed.

### TECHNICAL FIELD

The present invention generally relates to wafer level chip scale packages (WLCSP), and deals more particularly with a WLCSP for MEMS type semiconductor devices that provides hermetic sealing and permits traditional wafer probing.

### BACKGROUND OF THE INVENTION

The continuing trend towards smaller and thinner integrated circuit (IC) chips has created a number of challenges from a packaging standpoint. The demand for miniaturization has resulted in the development of advanced packages such as chip scale packages and flip chips. Wafer level chip scale packages (WLCSP) greatly reduce the amount of real estate required to package each chip, since the package is only slightly larger than the chip itself. Another advantage of WLCSPs is that they facilitate test and burn-in before assembly, as an alternative to the known good die (KGD) testing. Traditional packaging techniques often rely on low-cost plastic molded, non hermetic packages, sometimes referred to as PEM (plastic encapsulated micro-electronics). The devices used in plastic packages are typically passivated so the chips can tolerate some level of exposure to moisture and active gasses that slowly penetrate the plastic housing. PEM provides the IC with some degree of mechanical support, but is not entirely effective in protecting active areas of the chip from the surrounding environment.

Several classes of electronic devices such as MEMS, laser diodes, pressure sensors, accelerometers, image sensors, etc. cannot use standard PEM packaging for a number of reasons. First, nearly all MEMS devices need “free space” above the active areas of the chip. Opto-electronic ICs and modules also need a photonic link: a light port or window. Accordingly in the past, expensive and labor intensive packaging methods have been employed such as TO-Cans to package MEMS and opto-electronic devices.

Traditional WLCSP, while cost effective and reliable, is not suitable for use with MEMS type devices because it does not provide hermetic sealing or the necessary free space above the active areas of the devices which are required to allow the devices to operate properly. Accordingly, there is a need in the art for a WLCSP capable of providing a hermetic seal for a variety of advanced electronic devices such as MEMS which do not interfere with device operation. The present invention is directed towards satisfying this need in the art.

### SUMMARY OF THE INVENTION

According to one aspect of the invention, a method is provided for making a hermetically sealed, wafer level chip scale package, comprising: providing a cap for protectively covering active areas on the chip, applying a layer of metalization on the one face of the cap, forming a continuous bead of solder completely surrounding the active chip area, assembling the cap on the chip so that the solder bead is positioned between and contacts the metalization layer in the area on the chip surrounding the active chip area, and melting the solder to form a continuous, hermetic seal around the active chip area between the cap and the chip. The solder bead is preferably formed using under bump metalization (UBM) by means of electro-plating. A spacer formed on the cap maintains a desired distance between the cap and the chip until the solder bead is re-flowed to bond the cap to the chip, following which the spacer is removed as a portion of the cap is die cut away from the chip.

According to another aspect of the invention, a method is provided for making a hermetically sealed, wafer level chip scale package comprising: providing a semiconductor wafer having a plurality of chip portions formed therein and providing a cap for protectively covering active areas on each of the chip portions. A layer of metalization is applied to one face of the cap following which a plurality of continuous, patterned beads of solder are applied to the metalization layer. The cap is brought into face-to-face contact with the wafer such that each of the continuous solder beads contacts and surrounds an active area of the corresponding chip portion. The solder beads are melted in order to bond the cap to each of the chip portions and thereby form a hermetic seal around the active areas of each of the chip portions. The method is completed by cutting the wafer into individual die.

Another aspect of the invention resides in providing a hermetically sealed, wafer level, chip scale package comprising a semiconductor chip substrate having an active circuit area, a cap for protectively covering the active area and a solder bead welded to the cap and to the chip substrate such that the bead completely surrounds and hermetically seals the active area on the chip.

Accordingly, it is a primary object of the present invention to provide a wafer level chip scale package that provides hermetically sealing of advanced electronic devices such as MEMS.

Another object of the invention is to provide a WLCSP as described above which allows the use of a variety of caps and does not intrude upon the free working space above the active areas on the chip.

A further object of the invention is to provide a WLCSP of the type mentioned above which is highly cost effective and is compatible with high throughput manufacturing environments.

These, and further objects and advantages of the present invention will be made clear or will become apparent during the course of the following description of a preferred embodiment of the present invention.

### BRIEF DESCRIPTION OF THE DRAWINGS

In the drawings which form an integral part of the specification and are to be read in conjunction therewith, and in which like reference numerals are employed to designate identical components in the various views:

FIG. 1 is a perspective view of an integrated circuit employing including a wafer level, chip scale package according to the preferred embodiment of the present invention, portions of the cap being broken away to reveal active areas on the chip;

FIGS. 2-10 are cross-sectional views through the chip shown in FIG. 1, and depicting successive steps of the method used to make the WLCSP of the present invention.

### DESCRIPTION OF THE PREFERRED EMBODIMENT

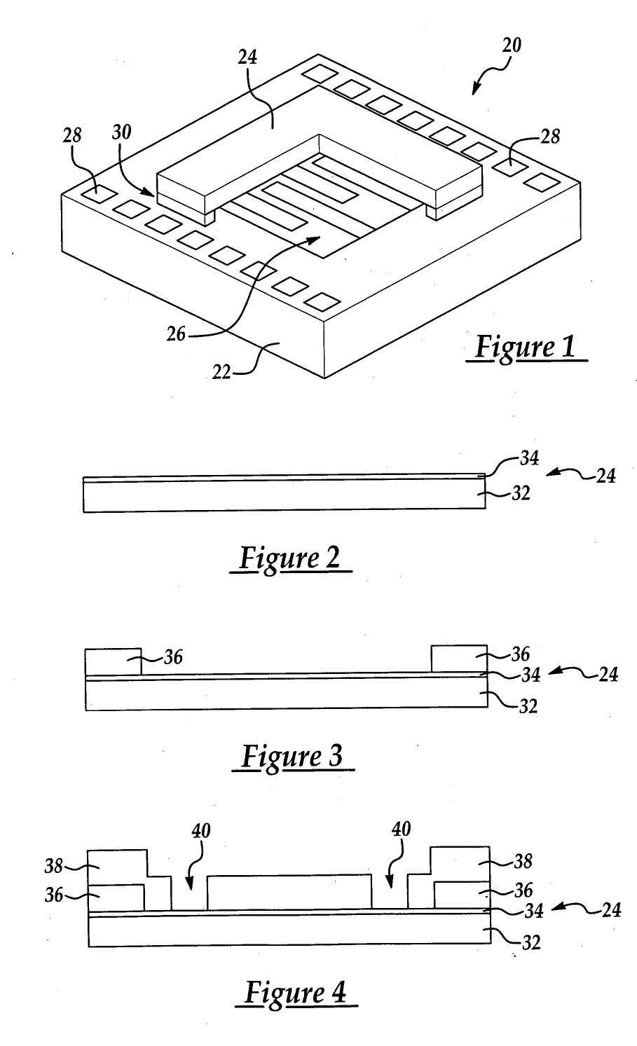

Referring first to FIG. 1, an integrated circuit generally indicated by the numeral 20 includes a semiconductor substrate 22 in which there is formed an integrated circuit or other electronic device within an active area 26 on the upper surface of the substrate 22. The active area 26 may include any of various MEMS type devices such as accelerometers, gyroscopes, micro-mirrors or the like. In accordance with the present invention, a cap 24 covers the active area 26 and is secured to the substrate 22 by an adhesive layer 30, which in the preferred embodiment, comprises a continuous bead of solder that surrounds the active area 26 and hermetically seals the volume between the cap 24 and the active area 26. The exact configuration and material used for the cap 24 will vary with the particular application and function of the chip 20, but by way of example, the cap 24 should be formed of a high barrier material such as a glass (for opto-electronic applications), LCP, silicon or ceramic. The cap 24 may provide both protective and functional purposes, such as forming a microlens, alignment structures, or merely a flat surface on the bottom of the cap. The chip 20 includes a plurality of bonding pads 28 on the upper surface of the substrate 22, outside the area of the cap 24, which permit connection, as by wire bonding, of the chip 20 to other, external electrical circuits.

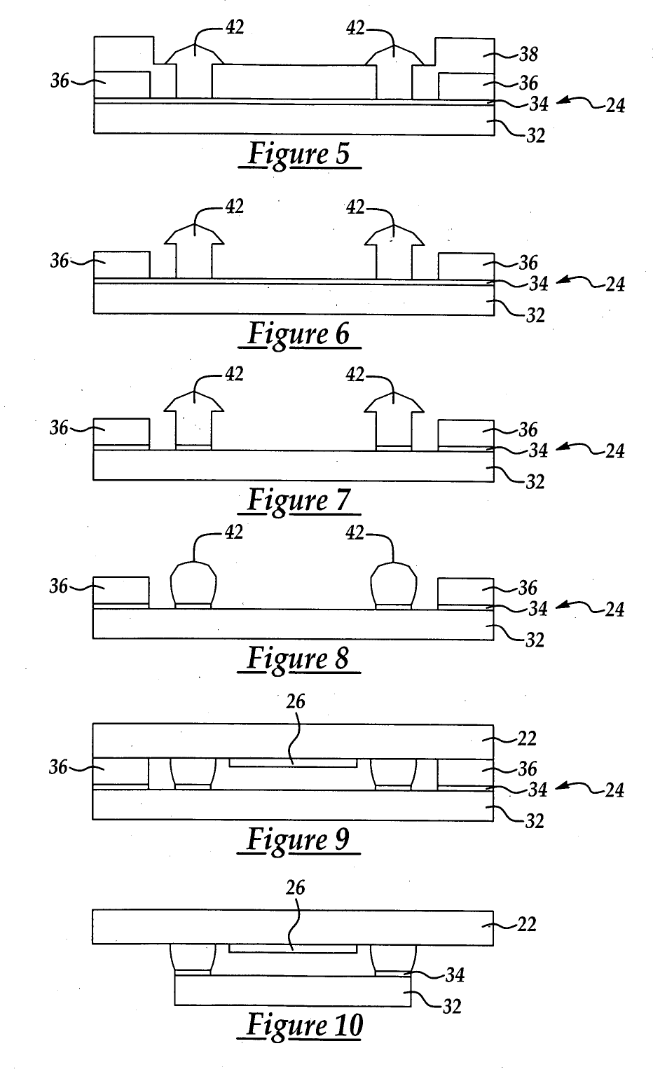

Referring now to FIG. 2, the first step in manufacturing the WLCSP of the present invention consists of applying a layer of under-bump metalization (UBM) 34 on one side of the cap 32. One UBM 34 suitable for use with a eutectic solder (63% Sn, 37% Pb) comprises layers of titanium and copper in 1000 angstrom and 4000 angstrom thicknesses, respectively. The UBM 34 is preferably applied by sputtering, but alternately, can be formed using other known techniques such as evaporation, stencil printing or jet printing, to name a few. Next, as shown in FIG. 3, a spacer 36 is formed around the outer periphery of the cap 32 for reasons that will become later apparent. The spacer 36 may be formed by depositing a layer of a dielectric material such as a polyimide onto the surface of the UBM layer 34. Then, as shown in FIG. 4, a mask in the form of a patterned layer 38 of photoresist is formed over the UBM layer 34 and the spacer 36. The photoresist layer 28 includes a channel like opening 40 therein which exposes a continuous path on the surface of the UBM layer 34. If desired, a layer (not shown) of dielectric material may be selectively deposited at various locations over the surface of the UBM layer 34 to provide electrical insulation and/or function as an additional moisture barrier.

Referring to FIG. 5, the next step in the fabrication process involves depositing, as by electroplating, a solder material, such as the eutectic solder mentioned above, through the channel opening 40 in the resist layer 38, onto the surface of the UBM layer 34. The solder 42 completely fills the channel opening 40 includes a generally spherical top surface. Following the electroplating step, the photoresist layer 38 is stripped away as shown in FIG. 6, leaving a continuous, upstanding wall of the solder 42, surrounded by the spacer 36, with a mushroom-like upper end. Next, as shown in FIG. 7, the exposed portions of the UBM layer 34 are removed, as by wet or dry etching, so that the only remaining portions of the UBM layer 34 are those beneath the spacer 36 and the solder 42. The cap assembly 24 is then placed in an infrared or vacuum oven and subjected to a temperature sufficient to melt and reflow the solder 42. As the solder 42 reflows, its mushroom-like upper end assumes a semispherical shape, as shown in FIG. 8, due to surface tension of the metal.

Next, with the cap assembly 24 competed, the chip substrate 22 and cap assembly 24 are aligned and brought into face-to-face contact, as shown in FIG. 9, with the spacer 36 facing the substrate 22, and the solder 42 in contact with the face of the chip 22, surrounding the active area 26. The assembly consisting of the cap assembly 24 and the substrate 22 is then subjected to an energy source, such as thermal radiation or ultrasonics, in order to raise the temperature of the solder 42 to a point that it melts and becomes welded to the substrate 22, thereby forming a continuous, hermetic seal between the substrate 22 and the cap 32 around the entire periphery of the active area 26.

The final step in the process is shown in FIG. 10. With the cap assembly 24 securely welded to the substrate 22, a portion of the cap 32 having the spacer 36 secured thereto is cut away using conventional die cutting techniques, leaving only that portion of the cap 32 which directly overlies the active area 26. As energy is applied to the solder 42 during the welding process, the solder melts and the substrate 22 and cap 32 are pressed together to form the weld. During this welding process, the spacer 36 comes into contact with one face of the substrate 22, in order to maintain a desired spacing between the substrate 22 and cap 32.

The inventive process method set out above had been described relative to packaging a single IC, however in practice, the process is carried out on a wafer level. Thus, at the wafer manufacturing level, the cap 32 will extend over an entire wafer and the spacers 36 and solder beads 42 will be formed around each chip portion that are later cut into individual die. Therefore, the last steps shown in FIG. 10 of cutting away excess portions of the cap 32 is performed as the wafer is cut into individual die.

From the foregoing, it is apparent that the wafer level, chip scale package described above not only provides for the reliable accomplishment of the objects of the invention, but it does so in a particularly economical and efficient manner. It is recognized, of course, that those skilled in the art may make various modifications or additions to the preferred embodiment chosen to illustrate the invention without departing from the spirit and scope of the present contribution to the art.

Accordingly, it is to be understood that the protections sought and to be afforded hereby should be deemed to extend to the subject matter claimed and all equivalents thereof fairly within the scope of the invention.

1. A method of making a hermetically sealed, wafer level chip scale package, comprising the steps of:
(A) providing a cap for protectively covering active areas on the chip;
(B) applying a layer of metalization on one face of the cap;
(C) forming a continuous bead of solder completely surrounding the active chip area;
(D) assembling the cap and the chip with the solder bead positioned between and contacting the metalization layer and the area on the chip surrounding the active chip area; and,
(E) melting the solder bead to form a continuous, hermetic seal around the active chip area between the cap and the chip.

2. The method of claim 1, wherein step (C) includes forming the solder bead on the face of the cap having the layer of metalization.

3. The method of claim 2, wherein step (C) includes:
applying a pattern mask over the metalization layer,
applying a layer of solder through the mask onto the metalization layer.

4. The method of claim 3, wherein applying the pattern mask includes depositing a layer of photoresist over the metalization layer, exposing and developing the photoresist, and stripping exposed areas of the photoresist to achieve a desired mask pattern.

5. The method of claim 1, wherein step (C) includes an electroplating process step.

6. The The method of claim 1, wherein step (C) includes:
forming a photoresist pattern mask over the metalization layer,
electroplating a layer of solder material through the mask onto the metalization layer, and
striping away the photoresist pattern mask.

7. The method of claim 6, wherein step (C) includes reflowing the solder layer to form the solder bead.

8. The method of claim 7, including the steps of:
bonding a spacer onto the cap, and
after step (E) is performed, cutting away a portion of the cap that includes the spacer.

9. The method of claim 1, including the step of forming a spacer on the cap, and wherein:
step (C) is performed by electroplating a layer of solder through a pattern mask onto the metalization layer,
step (D) includes bringing the spacer into face-to-face contact with chip, and
after step (E) is performed, cutting away a portion of the cap to which the spacer is bonded.

10.-11. (Cancelled).

12. A method of making a hermetically sealed, wafer level chip scale package, comprising the steps of:
(A) providing a semiconductor wafer having a plurality of chip portions formed therein, said wafer having a first face and a second opposite face,
(B) providing a cap for protectively covering active areas on each of the chip portions;
(C) applying a layer of metalization on one face of the cap;
(D) applying a plurality of continuous, patterned beads of solder to the metalization layer;
(E) bringing the cap into face-to-face contact with the wafer such that each of the continuous solder beads contacts and surrounds an active area of a corresponding chip portion;
(F) melting the solder to bond the cap to each of the chip portions and thereby form a hermetic seal around the active areas of each of the chip portions; and,
(G) cutting the wafer into individual die.

13. The method of claim 12, including applying a plurality of spacers on the cap to maintain a desired spacing between the cap and the wafer.

14. The method of claim 13, wherein step (G) includes cutting away portions of the cap having the spacers applied thereto.

15. The method of claim 12, wherein step (D) is performed by electroplating a layer of solder material through a pattern mask onto the metalization layer.

16. The method of claim 15, including the steps of removing the pattern mask and then reflowing the solder beads.

17.-25. (Cancelled)
